(19) United States
(12) Patent Application Publication
(10) Pub. No.: US 2026/0313903 A1
(43) Pub. Date: Oct. 8, 2026

(54) MEMORY DEVICES HAVING TRANSISTOR GATE STACKS WITH MULTIPLE METAL REGIONS

(71) Applicant: Micron Technology, Inc., Boise, ID (US)

(72) Inventors: Mojtaba Asadirad, Boise, ID (US); Pengyuan Zheng, Boise, ID (US); Yongjun Jeff Hu, Boise, ID (US); Umeshwarnath Surendranathan, Boise, ID (US); Michael James Irwin, Boise, ID (US)

(21) Appl. No.: 19/173,258

(22) Filed: Apr. 8, 2025

(51) Int. Cl. H10B 43/40; H10B 41/41

(52) U.S. Cl. CPC H10B 43/40; H10B 41/41

(57) ABSTRACT

A variety of applications can include apparatus having a memory device structured with one or more transistors in a periphery to a memory array in which each of the one or more transistors has a transistor gate stack with multiple metal regions. The multiple metal regions include a tungsten silicon nitride film between and contacting a tungsten silicide film in the gate stack and a tungsten nitride film in the gate stack. The gate stack can include a film containing titanium between and contacting the tungsten nitride film and a polysilicon region, where the polysilicon region is separated from a channel structure by a gate dielectric of the respective transistor.

### FIELD OF THE DISCLOSURE

Embodiments of the disclosure relate generally to electronic devices and systems and, more specifically, to components of memory devices and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data, and includes random-access memory (RAM), dynamic random-access memory (DRAM), static RAM (SRAM), and synchronous dynamic random-access memory (SDRAM) among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others.

Flash memory is utilized as non-volatile memory for a wide range of electronic applications. Flash memory devices typically include one or more groups of one-transistor, floating gate or charge trap memory cells that allow for high memory densities, high reliability, and low power consumption. Two common types of flash memory array architectures include NAND and NOR architectures, named after the logic form in which the basic memory cell configuration of each is arranged. The memory cells of the memory array are typically arranged in a matrix. In an example, the gates of each floating gate memory cell in a row of the array are coupled to an access line (e.g., a word line). In a NOR architecture, the drains of each memory cell in a column of the array are coupled to a data line (e.g., a bit line). In a NAND architecture, the drains of each memory cell in a string of the array are coupled together in series, source to drain, between a source line and a data line. Memory arrays of flash memory devices are being designed as 3D structures to increase memory density. For continued increases in memory capacity, various design considerations should be implemented for enhancements to reduce circuit area or limit increases of circuit area in a memory die.

### BRIEF DESCRIPTION OF THE DRAWINGS

The drawings, which are not necessarily drawn to scale, illustrate generally, by way of example, but not by way of limitation, various embodiments discussed in the present document.

FIG. 1 is a representation of a gate stack of a transistor that can be implemented in the periphery to a memory array of a memory device.

FIG. 2 is a representation of possible effects of high power sputter deposition of titanium nitride for a metal stack of a gate stack of a transistor.

FIG. 3 represents a gate stack that can be implemented in a transistor in circuitry of a periphery of a memory device that can address a high voltage fixed charge, in accordance with various embodiments.

FIG. 4 represents a gate stack that can be implemented in a transistor in circuitry of a periphery of a memory device that can address a high voltage fixed charge issue and gate agglomeration, in accordance with various embodiments.

FIG. 5 is a flow diagram of features of an example method of forming a memory device, in accordance with various embodiments.

FIG. 6 is a block diagram of regions of an example memory device having a three-dimensional memory array with a periphery to the memory array below the memory array in which a transistor in circuitry of the periphery that can be implemented to address a high voltage fixed charge issue and gate agglomeration, in accordance with various embodiments.

FIG. 7 is a schematic of an embodiment of an example memory device that can include an architecture in which selected transistors in a periphery to a memory array of memory device can be structured with a gate stack having a mutlti-metal stack, in accordance with various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction perpendicular to the horizontal as defined above. Various features can have a vertical component to the direction of their structure. The various embodiments are not necessarily mutually exclusive, as some embodiments can be combined with one or more other embodiments to form new embodiments. The following detailed description is, therefore, not to be taken in a limiting sense.

In a memory device structured as an semiconductor-based IC, also referred to as chip, the memory device can include an array of memory cells and a periphery to the area. The periphery includes circuitry to control and maintain the health of the memory device and circuitry to perform read and write operations. The periphery circuit can include complementary metal oxide semiconductor (CMOS) devices and other transistors, where a CMOS device includes a n-channel metal-oxide-semiconductor (MOS) field effect transistor (FET) and a p-channel MOSFET. Gates of the MOSFETs can be a conductive material other than a metal. It is a goal of design and fabrication to structure sets of CMOS devices or other transistors in the periphery to meet operational specifications, for example, but not limited to the speed of operation. To meet such operational specifications, materials and structural arrangement of components of these devices in the periphery can be selected to meet operational specifications. For example, CMOS devices of a NAND memory device can be structured with gate stacks including tungsten (W) for high speed applications greater than about 4.2 gigatransfers per second (GT/s). A gate stack is a stack of materials that includes conductive regions arranged on each other that is operable as a gate in a MOS transistor. A gate stack can include a metal stack on polysilicon, where the polysilicon of the gate stack is on and contacting a gate dielectric on a channel structure, and a protective insulating region on the metal stack. A gate stack including W to meet operational specifications, such as but not limited to transfer speed, should be designed to handle a high thermal budget (DT) of a process flow in fabrication of the memory device.

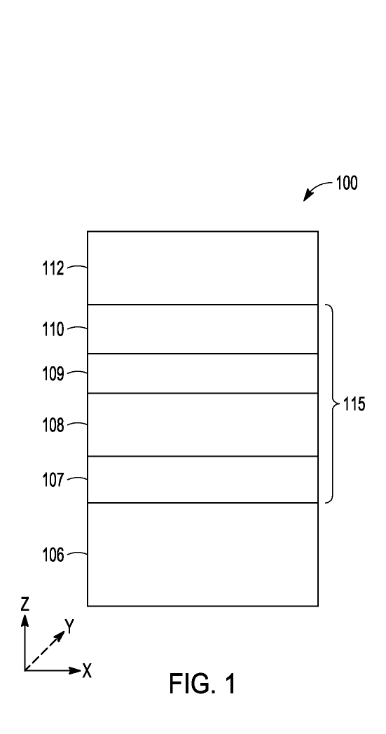

FIG. 1 is a representation of a cross-sectional view of a gate stack 100 of a transistor that can be implemented in the periphery to a memory array of a memory device. The cross-sectional view is in the z (vertical) – x plane. The regions of the components of the transistor shown in FIG. 1 are not drawn to scale. Gate stack 100 can include a protective insulating region 112 on and contacting a metal stack 115 that is on and contacting a polysilicon region 106. The source and drain of the transistor run in the y-direction. Metal stack 115 can be structured as metal films. One or more of the metal films can be formed by sputtering. Metal stack 115 can include a titanium nitride (TiN_{X}) film 107 on polysilicon region 106, a tungsten nitride (WN_{X}) film 108 on and contacting TiN_{X} film 107, a tungsten silicide (WSi_{X}) film 109 on and contacting WN_{X} film 108, and a W film 110 on and contacting protective insulating region 112. Protective insulating region 112 can be, but is not limited to, a plasma-enhanced chemical vapor deposition (PECVD) nitride film. The nitride film can be, but is not limited to, a silicon nitride (SiN_{X}) film. TiN_{X} film 107 can function as a diffusion barrier film and form an ohmic contact with polysilicon region 106, where polysilicon region 106 functions as a gate separated from a channel structure by a gate dielectric. WN_{X} film 108 can function as a meta-stable film for N supply under a DT for processing the transistor in an IC such as a memory die. WSi_{X} film 109 can function as a film to control grain growth. W film 110 can function to set the gate sheet resistance of the transistor.

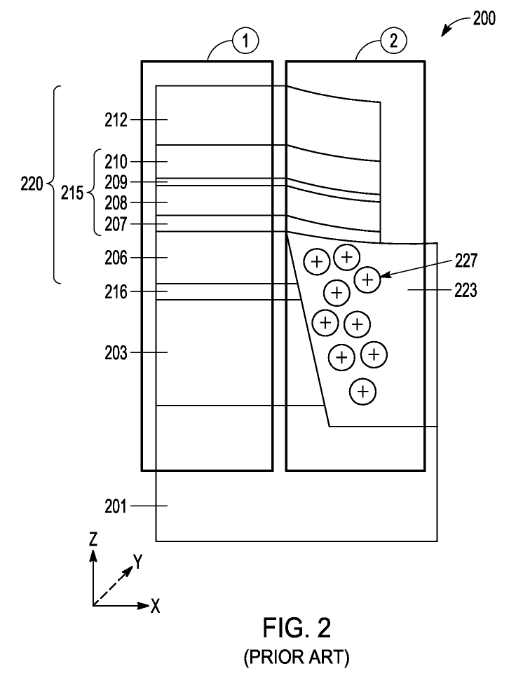

FIG. 2 is a cross-sectional representation of possible effects of high power sputter deposition of TiN_{X} for a metal stack 215 of a gate stack 220 of a transistor 200. The cross-sectional view is in the z (vertical) – x plane. The regions of transistor 200 shown in FIG. 2 are not drawn to scale. Region 1 represents one section of a layout of transistor 200 that includes a p-type well 203 in a silicon substrate 201 with a gate dielectric 216 on p-type well 203 and gate stack 220 on and contacting gate dielectric 216. The source and drain of transistor 200 run in the y-direction with a channel structure in region 1 between the source and the drain. Gate stack 220 includes a SiN_{X} film 212 on metal stack 215 that is on and contacting a n+ polysilicon region 206. Metal stack 215 can include a W film 210 on and contacting a WSi_{X} film 209 that is on a WN_{X} film 208 that is on and contacting a TiN_{X} film 207, where TiN_{X} that has been formed by a high power sputter depositon. Region 2 represents another section of the layout of transistor 200 illustrating metal stack 215 of gate stack 220 overhanging a shallow trench isolation (STI) 223, where metal stack 215 is wider than the channel structure in region 1 between the source and the drain of transistor 200 that abutts STI 223. Transistor 200 can be configured as a high voltage (HV) transistor having a lightly doped channel in p-type well 203 adjacent gate dielectric 216. In the periphery to a memory array of a memory device, high voltages are around 30 V relative to low voltages of around 3 V associated with logic circuits. The HV sputter deposition of TiN_{X} can result in charges in STI 223 including ionized Ti 227. A HV sputter deposition can use source powers around 15 KW. These charges can lead to leakage at voltages below the threshold voltage (V_{T}) of transistor 200, structured as a high voltage transistor, due to the charges in STI 223 depleting the charge in p-type well 203 due to the lightly channel. This phenomenon can be referred to as high voltage fixed charge (HV Qf). The transistor leakage can affect the circuits in which the HV transistor 200 is implemented and associated reliabilities.

In various embodiments, a metal stack of a gate stack of a transistor in circuitry of the periphery of a memory device can be structured to use a metal film formed at low power in place of the TiN_{X} sputtered at high power. Such a metal stack can address a root cause of HV Qf.

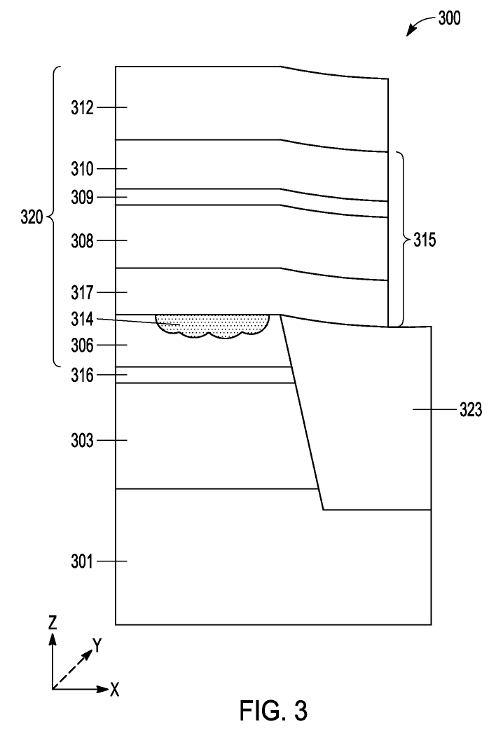

FIG. 3 represents a gate stack 320 of a transistor 300 that can be implemented in a transistor in circuitry of the periphery of a memory device that can address the HV Qf issue. The cross-sectional view is in the z (vertical) – x plane. The regions of transistor 300 shown in FIG. 3 are not draw to scale. Gate stack 320 can be on and contacting a gate dielectric 316 of transistor 300. The layout of gate stack 320 can be realized in CMOS devices in the periphery of a memory device, such as but not limited to, a NAND memory device. Gate stack 320 can include an insulating region 312 on and contacting a metal stack 315 that is on and contacting a polysilicon region 306 that is on gate dielectric 316. Gate dielectric 316 is on a p-type well 303 in a silicon substrate 301. The source and drain of transistor 300 run in the y-direction adjacent to a STI 323, with a channel structure under gate dielectric 316 between the source and the drain. Metal stack 315 overhangs STI 323, where metal stack 315 is wider than the channel structure between the source and the drain. Metal stack 315 can be formed over both polysilicon region 306 of transistor 300 and STI 323 adjacent transistor 300.

Metal stack 315 can include an arrangement of a W film 310 / a WSi_{X} film 309 / a WN_{X} film 308 / a Ti film 317. Ti film 317 can be formed at low power, for example, by a low power sputter within the range of about 500 W or less. The low power sputter can be in the range of about 150 W to about 300 W. Ti film 317 can include TiN_{X} formed by N diffusion from WN_{X} film 308 during further thermal processing of the device into which the transistor having gate stack 320 is being formed. Thickness of Ti film 317 and WN_{X} film 308 can be adjusted and nitrogen percentage (N%) of WN_{X} film 308 can be adjusted to ensure device yield and reliability are centered on target conditions. The implementation of Ti film 317 can substantially reduce or eliminate occurrence of unwanted charges in STI 323. Gate stack 320 can be implemented in periphery circuitry of a NAND memory device stack for high-speed NAND applications.

Though gate stack 320 having a metal stack 315 can have device yields that meet target conditions, reliability can be impacted by a gate agglomeration 314 of metal at the interface of Ti film 317 and polysilicon region 306. Gate agglomeration 314 can be an agglomeration of tungsten, titanium, or missing Si of polysilicon diffusing into polysilicon region 306 due to a thin diffusion barrier of initially formed Ti film 317. Gate agglomeration occurs with respect to N+ polysilicon region 306 for a gate of the transistor having metal stack 315, due to a N+ implant process. The gate agglomeration can be due to insufficient N supply from WN_{X} during thermal processing. The N supply limitations can occur since N from WN_{X} denudes to top and bottom of gate stack 320. This issue can be addressed by increasing WN_{X} thickness. However, WN_{X} thickness is sensitive and increased WN_{N} can bring back the HV Qf issue.

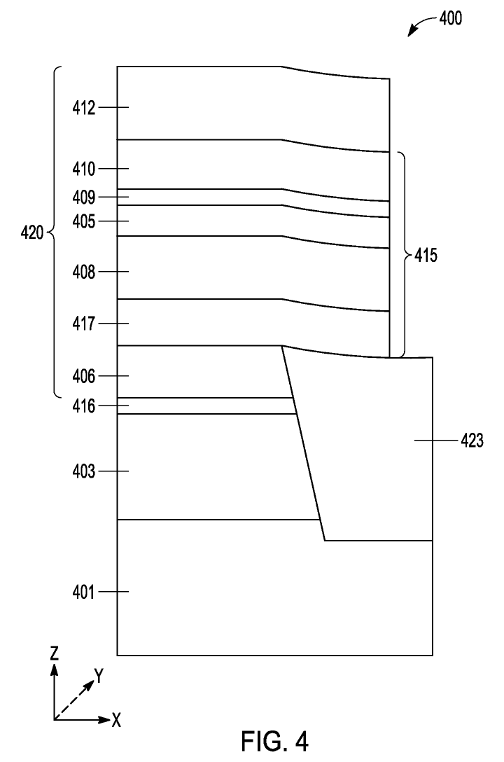

FIG. 4 represents a transistor 400, having a gate stack 420, that can be implemented in circuitry of the periphery of a memory device that can address the HV Qf issue and gate agglomeration. The cross-sectional view is in the z (vertical) – x plane. The regions of transistor 400 shown in FIG. 4 are not draw to scale. Gate stack 420 can be on and contacting a gate dielectric 416 of transistor 400. The layout of gate stack 420 can be realized in CMOS devices in the periphery of a memory device, such as but not limited to, a NAND memory device. Gate stack 420 can include an insulating region 412 on and contacting a metal stack 415 that is on and contacting a polysilicon region 406 that is on gate dielectric 416. Gate dielectric 416 is on a p-type well 403 in a silicon substrate 401. The source and drain of transistor 400 run in the y-direction adjacent to a STI 423, with a channel structure under gate dielectric 416 between the source and the drain. Metal stack 415 overhangs STI 423, where metal stack 415 is wider than the channel structure between the source and the drain. Metal stack 415 can be formed over both polysilicon region 406 of transistor 400 and STI 423 adjacent transistor 400.

Metal stack 415 can include an arrangement of a W film 410 / a WSi_{X} film 409 / a WSi_{X}N_{Y} film 405 / a WN_{X} film 408 / a film 417 containing Ti. Film 417 containing Ti can be formed at low power. Film 417 containing Ti can include TiN_{X} formed by N diffusion from WN_{X} film 408 during further thermal processing of the device into which the transistor having gate stack 420 is being formed after forming an initial Ti film. Thickness of film 417 containing Ti and WN_{X} film 408 can be adjusted and nitrogen percentage (N%) of WN_{X} film 308 can be adjusted. Thickness and other properties of WSi_{X}N_{Y} film 405 can be designed around the atomic % of N in WSi_{X}N_{Y} film 405. WSi_{X}N_{Y} film 405 can be situated on top of WNx film 408 aimed to improve N denude efficiency of WN_{X} film 308 and hence boost a TiN_{X} barrier within film 417 containing Ti. Film 417 containing Ti can be a graded TiN_{X} film, with x being less or equal to 1, from WN_{X} film 408.

Metal stack 415, post full device fabrication through various temperatures, can include film 417 containing Ti having a thickness in the range from about 15 Å to about 35 Å. As noted above, film 417 containing Ti can include a graded TiN_{X} composition. WN_{X} film 408 can have a thickness in the range of about 20 Å to about 60 Å. The N content of WN_{X} film 408 can be less than 50% atomic content of WN_{X} film 408. WSi_{X}N_{Y} film 405 can have a thickness of about 10 Å to about 40 Å. The total Si plus N content of WSi_{X}N_{Y} film 405 can be less than 67% atomic content of WSi_{X}N_{Y} film 405. W film 410 can have a thickness in the range from about 50 Å to about 500 Å. W film 410 can essentially be a pure W film. All films of metal stack 415 can be deposited in a temperature range from about room temperature to about 500 °C.

The implementation of Ti film 417 can substantially reduce or eliminate occurrence of unwanted charges in STI 423, and the implementation of WSi_{X}N_{Y} film 405 can substantially reduce or eliminate occurrence of unwanted agglomeration in polysilicon region 406. Gate stack 420 can be implemented in periphery circuitry of a NAND memory device stack for high-speed NAND applications.

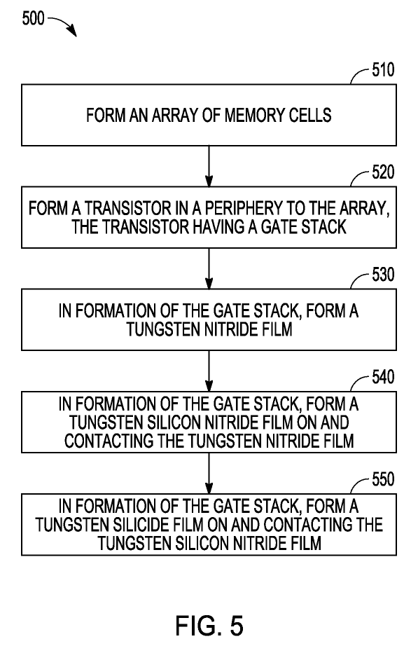

FIG. 5 is a flow diagram of features of an embodiment of an example method 500 of forming a memory device. At 510, an array of memory cells is formed. At 520, a transistor is formed in a periphery to the array, with the transistor having a gate stack. At 530, in formation of the gate stack, a WN_{X} film is formed. At 540, in formation of the gate stack, a WSi_{X}N_{Y} film is formed on and contacting the WN_{X} film. At 550, in formation of the gate stack, a WSi_{X} film is formed on and contacting the tungsten silicon nitride film. The array of memory cells can be formed before or after formation of the transistor in the periphery.

Variations of method 500 or methods similar to method 500 can include a number of different embodiments that may be combined depending on the application of such methods or the architecture or operational flow for which such methods are implemented. Such methods can include forming the WSi_{X} film by cutting off a nitrogen flow in forming the WSi_{X}N_{Y} film.

Variations can include forming the WN_{X} film on a Ti film, where the Ti film can be formed on a polysilicon region that is on and contacting a gate dielectric for the transistor above a channel structure for the transistor. Completion of the formation of the periphery can be performed in a temperature range such that the Ti film can be converted to a film containing titanium having a graded TiN_{X} structure with respect to nitrogen content. Thicknesses and nitrogen content for the WN_{X} film and the WSi_{X}N_{Y} can be controlled to locally optimize reduction of charge in a shallow trench insulator adjacent the transistor and reduction of agglomeration of tungsten, titanium, or missing Si of polysilicon at an interface of the film containing Ti and the polysilicon region.

Variations can include forming the tungsten nitride film, the tungsten silicon nitride film, and the tungsten silicide film as part of a metal stack of the gate stack. The metal stack can be formed on both a polysilicon region for the transistor and a shallow trench insulator adjacent the transistor. Variations of method 500 can include forming another transistor coupled to the transistor to form a CMOS device. A significant number of transistors having similar gate stack strutures that can differ by doping types, doping levels, V_{T}s, and other parameters that define p-type devices and n-type devices can be formed. The memory device can be, but is not limited to, a NAND memory device.

A memory device can include an array of memory cells and a periphery to the array, where the transistor in the periphery has a gate stack in which a WSi_{X}N_{Y} film is between and contacting a WSi_{X} film in the gate stack and a WN_{X} film in the gate stack. Variations of such a memory device and its features can include a number of different embodiments and features that may be combined depending on the application of such memory devices, the format of such memory devices, and/or the architecture in which such memory devices are implemented. Features of such memory devices can include atomic content of the combination of silicon and nitrogen in the WSi_{X}N_{Y} being less than about sixty-seventy percent. The atomic content of nitrogen in the WN_{X} film can be less than about fifty percent of the WN_{X} film.

Variations of such a memory device can include the gate stack having a film containing Ti between and contacting the WN_{X} film and a polysilicon region, where the polysilicon region is separated from a channel structure by a gate dielectric. The film containing Ti can have a graded TiN_{X} structure, where the grading is with respect to nitrogen content. Variations can include the gate stack having a W region above and contacting the WSi_{X} film.

Variations of such a memory device can include the tungsten nitride film, the tungsten silicon nitride film, and the tungsten silicide film structured as part of a metal stack of the gate stack. The metal stack can be positioned on both a polysilicon region for the transistor and a shallow trench insulator adjacent the transistor.

Variations of such a memory device can include the transistor structure being one transistor of two transistors in a CMOS device, where a second transistor of the two transistors has a gate stack structured the same as the gate stack of the first transistor. The transistor can be a portion of circuitry in the periphery structured for memory device applications greater than 4.2 GT/s.

A 3D memory array of a memory device can extend in a horizontal plane along a substrate, which can be designated as a x-y plane, and in a vertical direction, taken as the z direction perpendicular to the x-y plane. Other design considerations can be implemented with the 3D memory arrays such as using a circuit-under-array (CuA) architecture to enhance reduction of die size or increase utilization of space in a die. CuA refers generally to circuitry located in a memory die under a memory array of the memory die. The CuA region is a periphery to the 3D memory array. The CuA can include control logic and sensing circuitry for sensing the programmed data states of memory cells of the memory array. With the control logic and sensing circuitry fabricated below the memory array, using semiconductor processing that can include CMOS processing technology, CuA can be referred to as CMOS under array. One or more control circuits of the CuA can provide control signals to the 3D memory array in order to perform a read operation or a write operation on the 3D memory array. The CuA can include one or more of control circuitry, state machines, decoders, sense amplifiers, read/write circuits, and controllers. These circuits can implement one or more memory array operations including erasing, programming, or reading operations. For example, the CuA region can include an on-chip memory controller for determining row and column address, access line and data line addresses, memory array enable signals, and data latching signals. The operations on the 3D memory array are typically performed to access one or more memory cells in response to requests from other circuits on the memory die or a device external to the memory die. The CuA region can include pad structures to couple the memory array or one or more circuits in the CuA region to other portions of the die of the memory device, or to couple to devices external to the memory device. Various memory device formats can be structured in a CuA architecture, such as but not limited to NOR or NAND architecture semiconductor memory arrays.

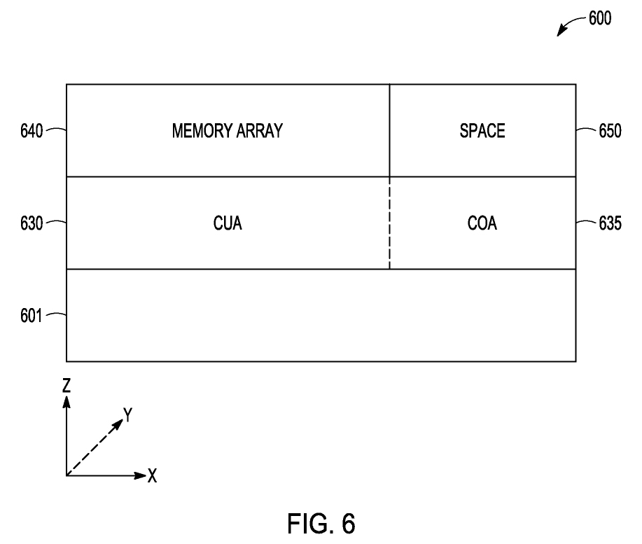

FIG. 6 is a block diagram of regions of an embodiment of an example memory device having a three-dimensional memory array with a periphery to the memory array below the memory array in which a transistor in circuitry of the periphery that can be implemented to address a high voltage fixed charge issue and gate agglomeration. A memory array region 640 having horizontal planes (x-y) of memory cells is disposed vertically over a CuA region 630 disposed in a substrate 601. The horizontal planes (x-y) of memory cells can be structured as multiple arranged tiers comprising memory cells. The CuA region 630 can include control circuitry for the memory array of the memory array region 640. The control circuitry in the CuA region 630 can include one or more instrumentalities such as a row decoder, column decoder, sense amplifiers, page buffers, selectors, I/O circuits, and one or more memory control units. A space 650 can be implemented adjacent the memory array region 640 and above the CuA region 630. The space 650 can be implemented beyond the horizontal extent of the memory array and may not directly contain elements of the control and sensing circuitry for the memory array, which can be located in the CuA region 630. The CuA region 630 can include a space of the CuA located directly below the 3D memory array of memory array region 640 such that this space of the CuA extends at least in one direction in the x-y plane to the same extent as the 3D memory array extends in this direction. The CuA region 630 can include a region in the die outside of the horizontal extent of the 3D memory array, referred to as OA, and below a level of the 3D memory array. In various embodiments, circuits or contacts can be structured outside the horizontal extent of and below a level of the 3D memory array. The circuits in this OA region can be referred to as circuits-outside-array, CoA, in a CoA region 635. The space of the CoA can be disposed adjacent the portion of the space of the CuA region 630 that contains control circuitry for the memory array of the memory array region 640 and below the level of the 3D memory array. In various embodiments, CMOS devices having multi-metal gate stacks can be located in CuA region 630 or CoA region 635. In memory devices without a CuA architecture, CMOS devices having multi-metal gate stacks can be located in a periphery adjacent to a memory array and coupled to the memory array. Such a periphery can be located similar to space 650.

With the memory device 600 having a CoA region 635 adjacent the CuA region 630 containing control circuitry for the memory array and placed below a level of the memory array in memory array region 640, the space 650 can be arranged directly over the CoA region 635. The CoA region 635 can include pads to couple to nodes for external connections or pins of the package for the memory device 600. The space 650 can also be implemented with conductive columns to couple to the top levels of the memory device 600.

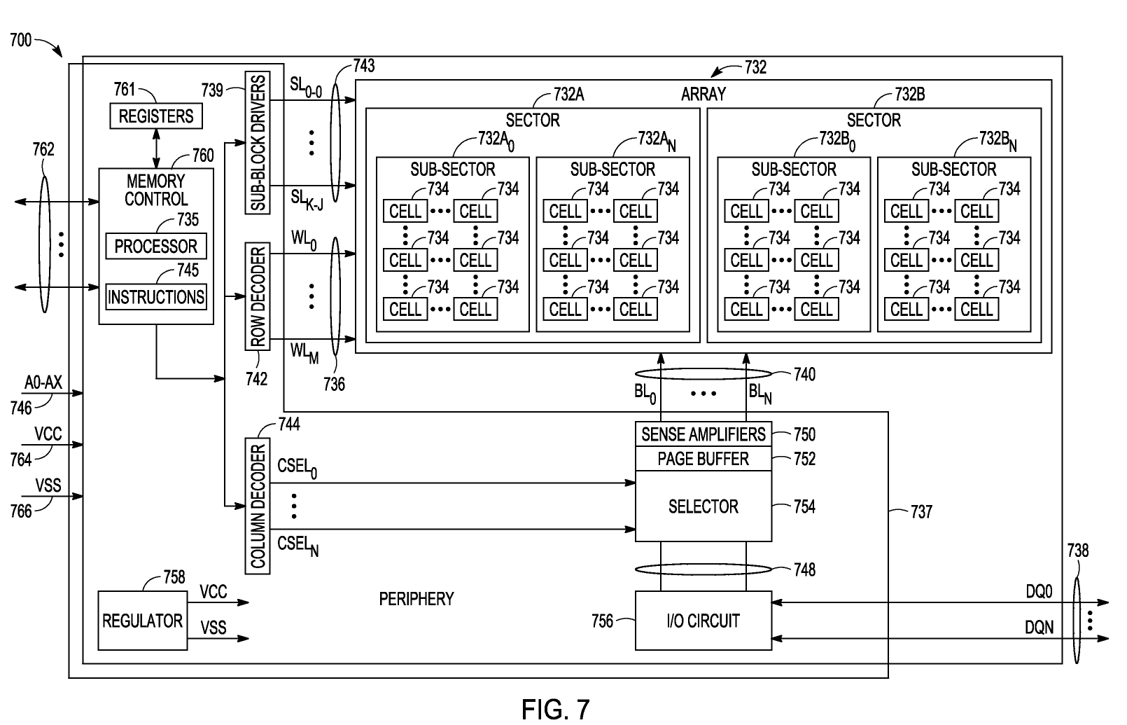

FIG. 7 is a schematic of an example memory device 700 that can include an architecture in which selected transistors in a periphery 737 to a memory array 732 of memory device 700 can be structured with multi-metal gate stacks as taught herein. Memory device 700 can be a NAND memory device. Memory device 700 can include memory array 732 having a plurality of memory cells 734, periphery 737 to memory array 732, sense amplifiers 750, and one or more circuits or components to provide communication with memory array 732 or perform one or more memory operations on memory array 732. Memory device 700 can include one or more CMOS devices in the periphery and one or more CMOS devices in sense amplifiers 750 constructed having a structure as discussed with respect to FIG. 4. Memory cells 734 can be formed coupled to data lines, where these data lines couple to or are a part of data lines (BLs) 740 coupled to sense amplifiers 750. Memory device 700 can be a memory die, for example, a NAND memory die. Memory device 700 can include a row decoder 742, a column decoder 744, sub-block drivers 739, sense amplifiers 750, a page buffer 752, a selector 754, an I/O circuit 726, and a memory controller 760.

Memory controller 760 can include processing circuitry, including one or more processors 735, and can be configured to perform operations of the memory device 700 by executing instructions 745. Memory controller 760 can be coupled to registers 761 that can contain parameter data for memory controller 760. For purposes of the present example, instructions 745 may be performed by memory within or dedicated to memory controller 760. In other examples, at least some portion of the instructions executed by memory controller 760 may be stored in other memory structures and loaded, for example, into local (memory controller) memory for execution by the memory controller 760.

Memory cells 734 of memory array 732 can be arranged in blocks, such as first and second blocks 732A, 732B. Each block can include sub-blocks. For example, first block 732A can include first and second sub-blocks 732A₀, 732A_{N}, and second block 732B can include first and second sub-blocks 732B₀, 732B_{N}. Each sub-block can include a number of physical pages, with each page including a number of memory cells 734. Although illustrated herein as having two blocks, with each block having two sub-blocks, and each sub-block having a number of memory cells 734, in other examples, the memory array 732 can include more or fewer blocks, sub-blocks, memory cells, etc. In other examples, the memory cells 734 can be arranged in a number of rows, columns, pages, sub-blocks, blocks, etc., and accessed using, for example, access lines 736, data lines 740, or one or more select gates, source lines, etc.

Memory controller 760 can control memory operations of the memory device 700 according to one or more signals or instructions received on control lines 762, including, for example, one or more clock signals or control signals that indicate a desired operation (e.g., write, read, erase, etc.), or address signals (A0-AX) received on one or more address lines 746. One or more devices external to memory device 700 can control the values of the control signals on control lines 762 or address signals on address line 746. Examples of devices external to memory device 700 can include, but are not limited to, a host, an external memory controller, a processor, or one or more circuits or components not illustrated in FIG. 7.

Memory device 700 can use access lines 746 and data lines 740 to transfer data to (e.g., write or erase) or from (e.g., read) one or more of memory cells 734. Row decoder 742 and column decoder 744 can receive and decode address signals (A0-AX) from address lines 746, determine which of memory cells 734 are to be accessed, and provide signals to one or more of access lines 736 (e.g., one or more of a plurality of access lines (WL₀-WL_{M})) or data lines 740 (e.g., one or more of a plurality of data lines (BL0-BLN)). Memory device 700 can include sense circuitry, such as sense amplifiers 750, configured to determine the values of data on (e.g., read), or to determine the values of data to be written to, memory cells 734 using data lines 740.

One or more devices external to the memory device 700 can communicate with memory device 700 using I/O lines (DQ0-DQN) 738, address lines 746 (A0-AX), or control lines 762. I/O circuit 756 can transfer values of data in or out of memory device 700, such as in or out of page buffer 752 or memory array 732, using I/O lines 738, according to, for example, control lines 762 and address lines 746. Page buffer 752 can store data received from the one or more devices external to memory device 700 before the data is programmed into relevant portions of memory array 732, or can store data read from memory array 732 before the data is transmitted to the one or more devices external to the memory device 700.

Column decoder 744 can receive and decode address signals (A0-AX) into one or more column select signals (CSEL₁-CSEL_{N}). Selector 754 (e.g., a select circuit) can receive the column select signals (CSEL₁-CSEL_{N}) and select data in page buffer 752 representing values of data to be read from or to be programmed into memory cells 734. Selected data can be transferred between page buffer 752 and the I/O circuit 726 using second data lines 748.

Memory controller 760 can receive positive and negative supply signals, such as a supply voltage (Vcc) 764 and a negative supply (Vss) 766 (e.g., a ground potential) with respect to Vcc, from an external source or supply (e.g., an internal or external battery, an alternating current (AC) to direct current (DC) converter, etc.). In certain examples, memory controller 760 can include a regulator 758 to internally provide positive or negative supply signals.

Based on an address provided by a user device, memory controller 760 can select any one sub-block or all sub-blocks. Memory controller 760 can generate the sub-block address to the sub-block drivers 739 and select any one sub-block or all sub-blocks. Memory controller 760 can send the WL information to the row decoder 742 and a column address to the column decoder 744.

Sub-block drivers 739 can include a number of independent drivers that generate signals to select lines 743 SL₀₋₀ . . . SL_{K-J}. These select lines can be coupled to different select devices in different blocks. Multiple input signals can be assigned to each individual driver, depending on the different voltages designed for operation of the respective driver during erase operations, program operations, and read operations. From the sub-block drivers 739, appropriate operational signals can be sent to the memory array 732 via the select lines 743 (SL_{(sub-block #)-(SGD # or SGS #)}) SL₀₋₀ . . . SL_{K-J}.

The following are example embodiments of devices and methods, in accordance with the teachings herein.

An example memory device 1 can comprise an array of memory cells and a periphery to the array, where the periphery can include a transistor, the transistor having a gate stack in which a tungsten silicon nitride film is between and contacting a tungsten silicide film in the gate stack and a tungsten nitride film in the gate stack.

An example memory device 2 can include features of example memory device 1 and can include atomic content of combination of silicon and nitrogen in the tungsten silicon nitride being less than about sixty-seventy percent.

An example memory device 3 can include features of any of the preceding example memory devices and can include atomic content of nitrogen in the tungsten nitride film being less than about fifty percent.

An example memory device 4 can include features of any of the preceding example memory devices and can include the gate stack to include a film containing titanium between and contacting the tungsten nitride film and a polysilicon region, the polysilicon region separated from a channel structure by a gate dielectric.

An example memory device 5 can include features of example memory device 4 and any of the preceding example memory devices and can include the film containing titanium having a graded titanium nitride structure with respect to nitrogen content.

An example memory device 6 can include features of any of the preceding example memory devices and can include the gate stack to include a tungsten region above and contacting the tungsten silicide film.

An example memory device 7 can include features of any of the preceding example memory devices and can include the tungsten nitride film, the tungsten silicon nitride film, and the tungsten silicide film being part of a metal stack of the gate stack, and the metal stack being positioned on both a polysilicon region for the transistor and a shallow trench insulator adjacent the transistor.

An example memory device 8 can include features of any of the preceding example memory devices and can include the transistor being a first transistor of two transistors in a complementary metal-oxide semiconductor (CMOS) device and a second transistor of the two transistors having a gate stack structured the same as the gate stack of the first transistor.

An example memory device 9 can include features of any of the preceding example memory devices and can include the transistor being a portion of circuitry in the periphery structured for memory device applications greater than 4.2 gigatransfers per second.

In an example memory device 10, any of the memory devices of example memory devices 1 to 9 may be incorporated into an electronic apparatus further comprising a host processor or memory controller and a communication bus extending between the host processor/memory controller and the memory device.

In an example memory device 11, any of the memory devices of example memory devices 1 to 10 may be modified to include any structure presented in another of example memory device 1 to 9.

In an example memory device 12, any apparatus associated with the memory devices of example memory devices 1 to 11 may further include a machine-readable storage device configured to store instructions as a physical state, wherein the instructions may be used to perform one or more operations of the apparatus.

In an example memory device 13, any of the memory devices of example memory devices 1 to 12 may be formed or operated in accordance with any of the below example methods 1 to 10.

An example memory device 14 can comprise an array of memory cells and a periphery to the array, where the periphery contains circuitry to control reading and writing data to the array, with the circuitry having a set of transistors with each transistor of the set having a tungsten silicon nitride film above and contacting a tungsten nitride film in a gate stack of the transistor. The tungsten silicon nitride film can have a thickness in a range between ten angstroms and forty angstroms.

An example memory device 15 can include features of example memory device 14 and can include the tungsten nitride film having a thickness in a range between about twenty angstroms and about sixty angstroms.

An example memory device 16 can include features of any of the preceding example memory devices 14 to 15 and can include the gate stack of each transistor of the set to include a film containing titanium between and contacting the tungsten nitride film and a polysilicon region, the polysilicon region separated from a channel structure by a gate dielectric of the respective transistor.

An example memory device 17 can include features of example memory device 16 and any of the preceding example memory devices 14 to 15 and can include the film containing titanium having a graded titanium nitride structure with respect to nitrogen content.

An example memory device 18 can include features of example memory device 16 and any of the preceding example memory devices 14 to 15 and 17 and can include the film containing titanium having a thickness in a range between about fifteen angstroms and about thirty-five angstroms.

An example memory device 19 can include features of any of the preceding example memory devices 14 to 18 and can include the gate stack to include a tungsten region separated from the tungsten silicon nitride film by a tungsten silicide film.

An example memory device 20 can include features of any of the preceding example memory devices 14 to 19 and can include the memory device being a NAND memory device with the circuitry located in the periphery below the array of memory cells.

In an example memory device 21, any of the memory devices of example memory devices 14 to 20 may be incorporated into an electronic apparatus further comprising a host processor or memory controller and a communication bus extending between the host processor/memory controller and the memory device.

In an example memory device 22, any of the memory devices of example memory devices 14 to 21 may be modified to include any structure presented in another of example memory device 14 to 21.

In an example memory device 23, any apparatus associated with the memory devices of example memory devices 14 to 22 may further include a machine-readable storage device configured to store instructions as a physical state, wherein the instructions may be used to perform one or more operations of the apparatus.

In an example memory device 24, any of the memory devices of example memory devices 14 to 23 may be formed or operated in accordance with any of the below example methods 1 to 10.

An example method 1 of forming an memory device can comprise forming an array of memory cells and forming a transistor in a periphery to the array, where the transistor has a gate stack. The formation of the gate stack can include: forming a tungsten nitride film; forming a tungsten silicon nitride film on and contacting the tungsten nitride film; and forming a tungsten silicide film on and contacting the tungsten silicon nitride film.

An example method 2 of forming an memory device can include features of example method 1 of forming an memory device and can include forming the tungsten silicide film to include cutting off a nitrogen flow in forming the tungsten silicon nitride film.

An example method 3 of forming an memory device can include features of any of the preceding example methods of forming an memory device and can include forming the tungsten nitride film to include forming the tungsten nitride film on a titanium film, where the titanium film is formed on a polysilicon region that is on and contacting a gate dielectric for the transistor above a channel structure for the transistor.

An example method 4 of forming an memory device can include features of example method 3 of forming an memory device and any of the preceding example methods of forming an memory device and can include completing the formation of the periphery in a temperature range such the titanium film is converted to a film containing titanium having a graded titanium nitride structure respect to nitrogen content.

An example method 5 of forming an memory device can include features of example method 3 of forming an memory device and any of the preceding example methods of forming an memory device and can include thickness and nitrogen content for the tungsten nitride film and the tungsten silicon nitride being controlled to locally optimize reduction of charge in a shallow trench insulator adjacent the transistor and reduction of agglomeration of tungsten, titanium, or missing Si of polysilicon at an interface of the film containing titanium and the polysilicon region.

An example method 6 of forming an memory device can include features of any of the preceding example methods of forming an memory device and can include forming the tungsten nitride film, the tungsten silicon nitride film, and the tungsten silicide film as part of a metal stack of the gate stack; and forming the metal stack on both a polysilicon region for the transistor and a shallow trench insulator adjacent the transistor.

In an example method 7, any of the example methods 1 to 6 of forming an memory device may be performed in forming an electronic apparatus further comprising a host processor and a communication bus extending between the host processor and a memory system.

In an example method 8 of forming an memory device, any of the example methods 1 to 7 of forming an memory device may be modified to include operations set forth in any other of example methods 1 to 7.

In an example method 9 of forming an memory device, any of the example methods 1 to 8 of forming an memory device may be implemented at least in part through use of instructions stored as a physical state in one or more machine-readable storage devices.

An example method 10 of forming an memory device can include features of any of the preceding example methods 1 to 9 of forming an memory device and can include performing functions associated with any features of example memory devices 1 to 24.

An example machine-readable storage device storing instructions, that when executed by one or more processors, cause a machine to perform operations, can comprise instructions to perform functions associated with any features of example memory devices 1 to 24 or perform methods associated with any features of example methods 1 to 10 of forming an memory device.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A memory device comprising:
an array of memory cells;
a periphery to the array, the periphery including a transistor, the transistor
having a gate stack in which a tungsten silicon nitride film is between and contacting a tungsten silicide film in the gate stack and a tungsten nitride film in the gate stack.

2. The memory device of claim 1, wherein atomic content of combination of silicon and nitrogen in the tungsten silicon nitride is less than about sixty-seventy percent.

3. The memory device of claim 1, wherein atomic content of nitrogen in the tungsten nitride film is less than about fifty percent.

4. The memory device of claim 1, wherein the gate stack includes a film containing titanium between and contacting the tungsten nitride film and a polysilicon region, the polysilicon region separated from a channel structure by a gate dielectric.

5. The memory device of claim 4, wherein the film containing titanium has a graded titanium nitride structure with respect to nitrogen content.

6. The memory device of claim 1, wherein the gate stack includes a tungsten region above and contacting the tungsten silicide film.

7. The memory device of claim 1, wherein the tungsten nitride film, the tungsten silicon nitride film, and the tungsten silicide film are part of a metal stack of the gate stack, and the metal stack is positioned on both a polysilicon region for the transistor and a shallow trench insulator adjacent the transistor.

8. The memory device of claim 1, wherein the transistor is a first transistor of two transistors in a complementary metal-oxide semiconductor (CMOS) device and a second transistor of the two transistors has a gate stack structured the same as the gate stack of the first transistor.

9. The memory device of claim 1, wherein the transistor is a portion of circuitry in the periphery structured for memory device applications greater than 4.2 gigatransfers per second.

10. A memory device comprising:
array of memory cells; and
a periphery to the array, the periphery containing circuitry to control reading and writing data to the array, the circuitry having a set of transistors with each transistor of the set having a tungsten silicon nitride film above and contacting a tungsten nitride film in a gate stack of the transistor, the tungsten silicon nitride film having a thickness in a range between ten angstroms and forty angstroms.

11. The memory device of claim 10, wherein the tungsten nitride film has a thickness in a range between about twenty angstroms and about sixty angstroms.

12. The memory device of claim 10, wherein the gate stack of each transistor of the set includes a film containing titanium between and contacting the tungsten nitride film and a polysilicon region, the polysilicon region separated from a channel structure by a gate dielectric of the respective transistor.

13. The memory device of claim 12, wherein the film containing titanium has a graded titanium nitride structure with respect to nitrogen content.

14. The memory device of claim 12, wherein the film containing titanium has a thickness in a range between about fifteen angstroms and about thirty-five angstroms.

15. The memory device of claim 10, wherein the gate stack includes a tungsten region separated from the tungsten silicon nitride film by a tungsten silicide film.

16. The memory device of claim 10, wherein the memory device is a NAND memory device with the circuitry located in the periphery below the array of memory cells.

17. A method of forming a memory device, the method comprising:
forming an array of memory cells;
forming a transistor in a periphery to the array, the transistor having a gate stack,
formation of the gate stack including:
forming a tungsten nitride film;
forming a tungsten silicon nitride film on and contacting the tungsten
nitride film; and
forming a tungsten silicide film on and contacting the tungsten silicon
nitride film.

18. The method of claim 17, wherein forming the tungsten silicide film includes cutting off a nitrogen flow in forming the tungsten silicon nitride film.

19. The method of claim 17, wherein forming the tungsten nitride film includes forming the tungsten nitride film on a titanium film, the titanium film formed on a polysilicon region that is on and contacting a gate dielectric for the transistor above a channel structure for the transistor.

20. The method of claim 19, wherein the method includes completing the formation of the periphery in a temperature range such the titanium film is converted to a film containing titanium having a graded titanium nitride structure with respect to nitrogen content.

21. The method of claim 19, wherein thickness and nitrogen content for the tungsten nitride film and the tungsten silicon nitride are controlled to locally optimize reduction of charge in a shallow trench insulator adjacent the transistor and reduction of agglomeration of tungsten, titanium, or missing silicon of polysilicon at an interface of the film containing titanium and the polysilicon region.

22. The method of claim 17, wherein the method includes:
forming the tungsten nitride film, the tungsten silicon nitride film, and the tungsten
silicide film as part of a metal stack of the gate stack; and
forming the metal stack on both a polysilicon region for the transistor and a shallow
trench insulator adjacent the transistor.
